(19) United States
(12) Patent Application Publication
(10) Pub. No.: US 2022/0182050 A2
(43) Pub. Date: Jun. 9, 2022

(54) METHOD AND ARRANGEMENT FOR ACTUATING A METAL-OXIDE-SEMICONDUCTOR FIELD-EFFECT TRANSISTOR

(71) Applicant: Siemens Aktiengesellschaft, 80333 München (DE)

(72) Inventors: MARK-MATTHIAS BAKRAN, Erlangen (DE); JÜRGEN BÖHMER, Stein (DE); MARTIN HELSPER, Allersberg (DE); EBERHARD ULRICH KRAFFT, Nürnberg (DE); BERND LASKA, Herzogenaurach (DE); ANDREAS NAGEL, Nürnberg (DE); STEFAN HANS WERNER SCHÖNEWOLF, Nürnberg (DE); JAN WEIGEL, Grossenbuch (DE)

(73) Assignee: Siemens Aktiengesellschaft, 80333 München (DE)

(21) Appl. No.: 17/059,113

(22) PCT Filed: May 6, 2019
(86) PCT No.: PCT/EP2019/061493

§ 371 Date: Nov. 25, 2020

(30) Foreign Application Priority Data
May 29, 2018 (EP) 18174799.9

(51) Int. Cl. H03K 17/14; H03K 17/0814

(52) U.S. Cl. CPC H03K 17/145; H03K 17/08142

(57) ABSTRACT

The invention relates to a method and an actuation assembly (3) for actuating a MOSFET (1), in particular a MOSFET (1) based on a semiconductor with a wide band gap. According to the invention, a characteristic block is generated in which a change (ΔU1, ΔU2, ΔR1, ΔR2) in at least one actuation variable (U1, U2, R1, R2) for actuating the MOSFET (1) with respect to a reference actuation value of the actuation variable (U1, U2, R1, R2) is stored on the basis of at least one operating characteristic variable (U, T) which influences the switching behavior of the MOSFET (1), said change counteracting a change in the switching behavior as a result of the at least one operating characteristic variable (U, T). During the operation of the MOSFET (1), an actual value of the at least one operating characteristic variable (U, T) is ascertained, and the reference actuation value of the at least one actuation variable (U1, U2, R1, R2) is changed according to the characteristic block depending on the actual value of the at least one operating characteristic variable (U, T).

The invention relates to a method and an actuating arrangement for actuating a metal-oxide-semiconductor field-effect transistor (MOSFET), in particular a MOSFET based on a semiconductor with a wide band gap (wide-bandgap semiconductor).

The switching behavior of a MOSFET is strongly dependent upon operating conditions under which the MOSFET is operated, in particular an operating voltage which is applied between the drain and source of the MOSFET in the switched-off state of the MOSFET, and an operating temperature of the MOSFET. For applications of a MOSFET, a predictable and consistent switching behavior of the MOSFET is required in order to observe boundary conditions, for example for an overvoltage when switching off the MOSFET and for the electromagnetic compatibility. Particularly in applications with strongly fluctuating operating conditions, currently increasing use is being made of MOSFETs based on semiconductors with a wide band gap, for example in traction current converters, in which the operating voltage may fluctuate strongly.

The object underlying the invention is that of specifying a method and an actuating arrangement for actuating a MOSFET, which are improved with regard to the consistency of the switching behavior of the MOSFET under shifting operating conditions.

The object is achieved according to the invention by a method with the features of claim 1 and an actuating arrangement with the features of claim 8.

Advantageous embodiments of the invention are the subject matter of the subclaims.

In the method according to the invention for actuating a MOSFET, in particular a MOSFET based on a semiconductor with a wide band gap, a characteristic block is created in which, as a function of at least one operating characteristic variable influencing the switching behavior of the MOSFET, a change to at least one actuating variable used to actuate the MOSFET compared to a reference actuating value of the actuating variable is recorded, which change counteracts a change to the switching behavior due to the at least one operating characteristic variable. During operation of the MOSFET, an actual value of the at least one operating characteristic variable is ascertained and the at least one actuating variable is changed in comparison to its reference actuating value, according to the characteristic block, as a function of the actual value of the at least one operating characteristic variable.

The invention takes advantage of the fact that the dependency of the switching behavior of a MOSFET upon operating characteristic variables which influence the switching behavior can be mapped by characteristic curves in a very precise manner, which characteristic curves describe actuating variables used to actuate the MOSFET as a function of the operating characteristic variables. The invention makes provision for creating a characteristic block which has one or more characteristic curves, each of which having changes to an actuating variable compared to a reference actuating value as a function of at least one operating characteristic variable, which are necessary in order to counteract changes to the switching behavior due to the at least one operating characteristic variable. The actuating variables are set according to the characteristic block as a function of actual values of the at least one operating characteristic variable. As a result, the influence of at least one operating characteristic variable on the switching behavior of the MOSFET can be compensated, so that the switching behavior of the MOSFET is stabilized.

Embodiments of the invention make provision for the change to a switching-on actuating voltage for switching on the MOSFET, the change to a switching-off actuating voltage for switching off the MOSFET, the change to a switching-on gate resistance for switching on the MOSFET and/or the change to a switching-off gate resistance for switching off the MOSFET to be recorded in the characteristic block as a function of the at least one operating characteristic variable. In other words, these embodiments of the invention make provision for a switching-on actuating voltage, a switching-off actuating voltage, a switching-on gate resistance and/or a switching-off gate resistance for the MOSFET as a control variable in each case, the change to which is recorded in the characteristic block as a function of the at least one operating characteristic variable. These embodiments of the inventions advantageously enable a direct influencing of the gate-source voltage of the MOSFET for switching on and/or switching off the MOSFET as a function of the at least one operating characteristic variable.

Further embodiments of the invention make provision for the change to the at least one actuating variable as a function of an operating voltage and/or an operating temperature of the MOSFET to be recorded in the characteristic block. These embodiments of the invention take into consideration that the switching behavior of the MOSFET, above all else, depends upon the operating voltage and the operating temperature and, for this reason, above all else, the switching behavior of the MOSFET can be stabilized by compensating for the influences to these two operating characteristic variables.

An actuating arrangement according to the invention for performing the method according to the invention comprises an evaluation unit, which is embodied to store the characteristic block and ascertain the change to the at least one actuating variable as a function of the actual value of the at least one operating characteristic variable, on the basis of the characteristic block, and a control unit, which is embodied to actuate the MOSFET as a function of a control signal with an actuating value of the at least one actuating variable, which is changed compared to the reference actuating value of the actuating variable according to the change ascertained by the evaluation unit.

Embodiments of the actuating arrangement according to the invention make provision for the control unit to have a controllable switching-on voltage source for generating a variable switching-on actuating voltage for switching on the MOSFET, a controllable switching-off voltage source for generating a variable switching-off actuating voltage for switching off the MOSFET, a controllable switching-on resistance unit for generating a variable switching-on gate resistance for switching on the MOSFET and/or a controllable switching-off resistance unit for generating a variable switching-off gate resistance for switching off the MOSFET.

A further embodiment of the actuating arrangement according to the invention makes provision for a measurement apparatus for capturing actual values of at least one operating characteristic variable, the influence of which on the switching behavior of the MOSFET is taken into consideration in the characteristic block. For example, the measurement apparatus is embodied to capture actual values of an operating voltage and/or an operating temperature of the MOSFET.

An actuating arrangement according to the invention makes it possible to perform the method according to the invention. The advantages of an actuating arrangement according to the invention therefore correspond to the advantages of the method according to the invention already mentioned above, and are not listed separately once more here.

A current converter according to the invention, in particular a traction current converter, has at least one MOSFET, in particular a MOSFET based on a semiconductor with a wide band gap, and an actuating arrangement according to the invention for actuating the MOSFET. The invention is particularly suitable for actuating a MOSFET of a traction current converter, as the operating voltage of a traction current converter can strongly fluctuate and therefore vary the switching behavior of the MOSFET.

The above-described properties, features and advantages of this invention, as well as the manner in which they are realized, will become clearer and more intelligible in conjunction with the following description of exemplary embodiments which are explained in more detail in conjunction with the drawings, in which:

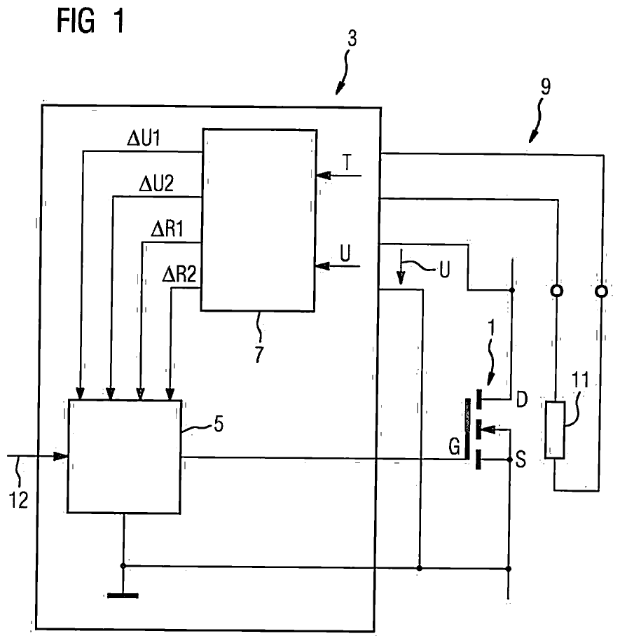

FIG. 1 shows a circuit diagram of a MOSFET and a first exemplary embodiment of an actuating arrangement for actuating the MOSFET,

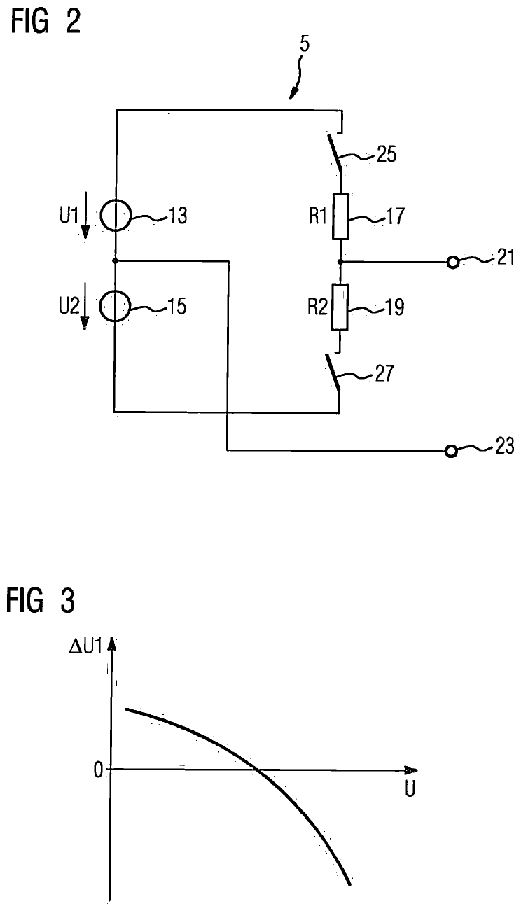

FIG. 2 shows a circuit diagram of a control unit for actuating a MOSFET,

FIG. 3 shows a characteristic curve for a change to a switching-on actuating voltage as a function of an operating voltage of a MOSFET,

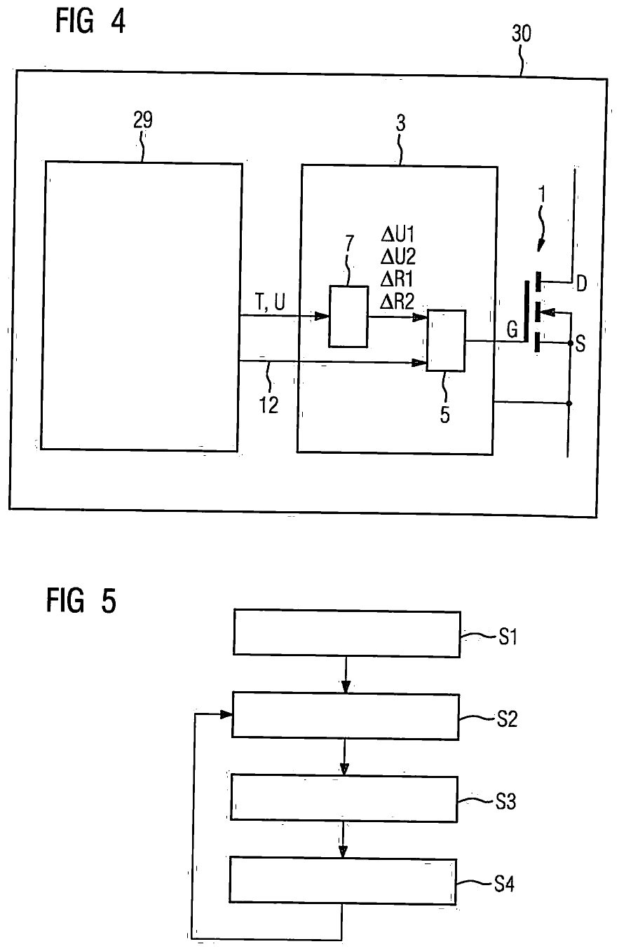

FIG. 4 shows a circuit diagram of a current converter,

FIG. 5 shows a flow diagram of a method for actuating a MOSFET.

Parts which correspond to one another are provided with the same reference characters in the figures.

FIG. 1 shows a circuit diagram of a MOSFET 1 and a first exemplary embodiment of an actuating arrangement 3 according to the invention for actuating the MOSFET 1.

The MOSFET 1 is embodied as a normally blocking n-channel MOSFET, which is based on a semiconductor with a wide band gap, for example on silicon carbide or gallium nitride.

The actuating arrangement 3 comprises a control unit 5, an evaluation unit 7 and a measurement apparatus 9.

The measurement apparatus 9 is embodied to capture an operating temperature T and an operating voltage U of the MOSFET 1 as operating variables T, U. In order to capture the operating temperature T, the measurement apparatus 9 has a temperature sensor 11, for example an NTC resistor (negative temperature coefficient thermistor). The operating voltage U, for example, is measured as a drain-source voltage of the MOSFET 1 between drain D and source S in the switched-off state of the MOSFET 1.

FIG. 2 shows a schematic circuit diagram of the control unit 5. The control unit 5 comprises a controllable switching-on voltage source 13 for generating a variable switching-on actuating voltage U1 for switching on the MOSFET 1, a controllable switching-off voltage source 15 for generating a variable switching-off actuating voltage U2 for switching off the MOSFET 1, a controllable switching-on resistance unit 17 for generating a variable switching-on gate resistance R1 for switching on the MOSFET 1, a controllable switching-off resistance unit 19 for generating a variable switching-off gate resistance R2 for switching off the MOSFET 1, a first terminal 21 connected to the gate G of the MOSFET 1 and a second terminal 23 connected to the source S of the MOSFET 1. The switching-on resistance unit 17 and the switching-off resistance unit 19, for example, each have a large number of individual resistors, wherein in order to set a particular switching-on gate resistance R1 or switching-off gate resistance R2, a number of individual resistors required for this purpose can be interconnected to one another in each case.

In each case, a first pole of the switching-on voltage source 13 and a first pole of the switching-off voltage source 15 are permanently connected to the second terminal 23. In order to switch on the MOSFET 1, the second pole of the switching-on voltage source 13 is connected to the first terminal 21 via the switching-on resistance unit 17 by closing a first switch 25, and the second pole of the switching-off voltage source 15 is disconnected from the switching-off resistance unit 19 and the first terminal 21 by opening a second switch 27. In order to switch off the MOSFET 1, the second pole of the switching-off voltage source 15 is connected to the first terminal 21 via the switching-odd resistance unit 19 by closing the second switch 27, and the switching-on voltage source 13 is disconnected from the switching-on resistance unit 17 and the first terminal 21 by opening the first switch 25. The switching on and off of the MOSFET 1 is triggered by a binary control signal 12 supplied to the control unit 5.

The switching-on actuating voltage U1 used to switch on the MOSFET 1 and the switching-on gate resistance R1 used to switch on the MOSFET 1, as well as the switching-off actuating voltage U2 used to switch off the MOSFET 1 and the switching-off gate resistance R2 used to switch off the MOSFET 1 are actuating variables U1, U2, R1, R2 for actuating the MOSFET 1, which are each set as a function of the operating temperature T and the operating voltage U of the MOSFET 1. To this end, stored in the evaluation unit 7 is a characteristic block, in which changes ΔU1, ΔU2, ΔR1, ΔR2 to said actuating variables U1, U2, R1, R2 compared to a reference actuating value as a function of the operating temperature T and the operating voltage U are recorded in each case, which changes counteract a change in the switching behavior of the MOSFET 1 caused by the operating temperature T or operating voltage U.

For the operating temperature T and the operating voltage U, which are captured by the measurement apparatus 9, the evaluation unit 7 uses the characteristic block to ascertain changes ΔU1, ΔU2, ΔR1, ΔR2 to the actuating variables U1, U2, R1, R2 compared to the respective reference actuating values thereof and transmits the changes ΔU1, ΔU2, ΔR1, ΔR2 to the control unit 5. The control unit 5 sets the switching-on actuating voltage U1, the switching-off actuating voltage U2, the switching-on gate resistance R1 and the switching-off gate resistance R2 to the respective actuating value which is changed compared to the reference actuating value.

FIG. 3 shows, by way of example, a characteristic curve of the characteristic block for a change ΔU1 to the switching-on actuating voltage U1 as a function of the operating voltage U compared to the reference actuating value for the switching-on actuating voltage U1. The value ΔU1 resulting from the characteristic curve for an operating voltage U is added to the reference actuating value for the switching-on actuating voltage U1.

FIG. 4 shows a circuit diagram of a current converter 30 with a MOSFET 1 and a second exemplary embodiment of an actuating arrangement 3 according to the invention for actuating the MOSFET 1. The current converter 30, for example, is a traction current converter with further MOSFETs 1 (not shown here), which are interconnected to form half bridges or full bridges in a known manner, and a further actuating arrangement 3 for each further MOSFET 1. The actuating arrangements 3 of this exemplary embodiment only differ from the exemplary embodiment shown in FIG. 1 in that they have no measurement apparatus 9 for capturing the operating temperature T and the operating voltage U of the MOSFET 1. Instead, actual values of the operating temperature T and the operating voltage U are supplied to the evaluation unit 7 of each actuating arrangement 3 by a controller 29 of the current converter 30, which also sends the control signal 12 to the control unit 5 of the actuating arrangement 3.

FIG. 5 shows a flow diagram of an exemplary embodiment of the method according to the invention for actuating a MOSFET 1 with an actuating arrangement 3 designed according to FIG. 1 or FIG. 4.

In a first method step S1, a characteristic block is created, in which a change ΔU1 to the switching-on actuating voltage U1, a change ΔU2 to the switching-off actuating voltage U2, a change ΔR1 to the switching-on gate resistance R1 and a change ΔR2 to the switching-off gate resistance R2, in each case as a function of the operating temperature T and the operating voltage U of the MOSFET 1, are recorded. The characteristic block is stored in the evaluation unit 7 of the actuating arrangement 3.

In a second method step S2, the instantaneous operating temperature T and the instantaneous operating voltage U of the MOSFET 1 (i.e. actual values of the operating temperature T and the operating voltage U) are ascertained and supplied to the evaluation unit 7.

In a third method step S3, for the values of the operating temperature T and the operating voltage U ascertained in the second method step S2, the evaluation unit 7 uses the characteristic block to ascertain changes ΔU1, ΔU2, ΔR1, ΔR2 to the switching-on actuating voltage U1, the switching-off actuating voltage U2, the switching-on gate resistance R1 and the switching-off gate resistance R2 compared to the respective reference actuating values thereof and transmit these to the control unit 5.

In a fourth method step S4, the control unit 5 sets the switching-on actuating voltage U1, the switching-off actuating voltage U2, the switching-on gate resistance R1 and the switching-off gate resistance R2 to an actuating value in each case, which is changed compared to the respective reference actuating value by adding the change ΔU1, ΔU2, ΔR1, ΔR2 ascertained in the third method step S3 to the reference actuating value. Following the fourth method step S4, the method is continued with the second method step S2.

The exemplary embodiments of an actuating arrangement 3 according to the invention and the method according to the invention, which are described on the basis of the figures, can be modified in various ways to form alternative exemplary embodiments. For example, changes ΔU1, ΔU2, ΔR1, ΔR2 to the switching-on actuating voltage U1, the switching-off actuating voltage U2, the switching-on gate resistance R1 and the switching-off gate resistance R2 compared to respective reference actuating values may be ascertained and set as a function of either only the operating temperature T or only the operating voltage U, instead of as a function of both the operating temperature T and the operating voltage U. Furthermore, provision may be made to ascertain and set changes ΔU1, ΔU2, ΔR1, ΔR2 only to a subset of the actuating variables U2, U2, R1, R2 compared to respective reference actuating values as a function of the operating temperature T and/or the operating voltage U, for example only changes ΔU1, ΔU2 to the switching-on actuating voltage U1 and the switching-off actuating voltage U2 or only changes ΔR1, ΔR2 to the switching-on gate resistance R1 and the switching-off gate resistance R2. Furthermore, in the case of taking into consideration the operating temperature T, provision may be made to ascertain the instantaneous operating temperature T of the MOSFET 1 on the basis of a temperature-dependent electrical parameter of the MOSFET 1, for example as in M. Denk and M. M. Bakran, “IGBT Gate Driver with Accurate Measurement of Junction Temperature and Inverter Output Current,” PCIM Europe 2017; International Exhibition and Conference for Power Electronics, Intelligent Motion, Renewable Energy and Energy Management, Nuremberg, Germany, 2017, pp. 1-8, or to determine the instantaneous operating temperature T with the aid of a model which estimates the operating temperature T using other operating conditions.

Exemplary embodiments of a current converter 19 alternative to FIG. 4 result from replacing the actuating arrangement 3 shown in FIG. 4 with an actuating arrangement 3 of the exemplary embodiment described in FIG. 1 or one of the modified exemplary embodiments previously mentioned.

Although the invention has been illustrated and described in greater detail on the basis of preferred exemplary embodiments, the invention is not limited by the disclosed examples and other variations can be derived herefrom by the person skilled in the art without departing from the scope of protection of the invention.

1. A method for actuating a MOSFET (1), in particular a MOSFET (1) based on a semiconductor with a wide band gap, wherein
a characteristic block is created in which, as a function of at least one operating characteristic variable (U, T) influencing the switching behavior of the MOSFET (1), a change (ΔU1, ΔU2, ΔR1, ΔR2) to at least one actuating variable (U1, U2, R1, R2) for actuating the MOSFET (1) compared to a reference actuating value of the actuating variable (U1, U2, R1, R2) is recorded, which change counteracts a change to the switching behavior due to the at least one operating characteristic variable (U, T),
during operation of the MOSFET (1), an actual value of the at least one operating characteristic variable (U, T) is ascertained and
the at least one actuating variable (U1, U2, R1, R2) is changed compared to its reference actuating value, according to the characteristic block, as a function of the actual value of the at least one operating characteristic variable (U, T).

2. The method as claimed in claim 1, wherein the change (ΔU1) to a switching-on actuating voltage (U1) for switching on the MOSFET (1) as a function of the at least one operating characteristic variable (U, T) is recorded in the characteristic block.

3. The method as claimed in one of the preceding claims, wherein the change (ΔU2) to a switching-off actuating voltage (U2) for switching off the MOSFET (1) as a function of the at least one operating characteristic variable (U, T) is recorded in the characteristic block.

4. The method as claimed in one of the preceding claims, wherein the change (ΔR1) to a switching-on gate resistance (R1) for switching on the MOSFET (1) as a function of the at least one operating characteristic variable (U, T) is recorded in the characteristic block.

5. The method as claimed in one of the preceding claims, wherein the change (ΔR2) to a switching-off gate resistance (R2) for switching off the MOSFET (1) as a function of the at least one operating characteristic variable (U, T) is recorded in the characteristic block.

6. The method as claimed in one of the preceding claims, wherein the change (ΔU1, ΔU2, ΔR1, ΔR2) to the at least one actuating variable (U1, U2, R1, R2) as a function of an operating voltage (U) of the MOSFET (1) is recorded in the characteristic block.

7. The method as claimed in one of the preceding claims, wherein the change (ΔU1, ΔU2, ΔR1, ΔR2) to the at least one actuating variable (U1, U2, R1, R2) as a function of an operating temperature (T) of the MOSFET (1) is recorded in the characteristic block.

8. An actuating arrangement (3) for performing the method as claimed in one of the preceding claims, the actuating arrangement (3) comprising
an evaluation unit (7), which is embodied to store the characteristic block and ascertain the change (ΔU1, ΔU2, ΔR1, ΔR2) to the at least one actuating variable (U1, U2, R1, R2) as a function of the actual value of the at least one operating characteristic variable (U, T), on the basis of the characteristic block, and
a control unit (5), which is embodied to actuate the MOSFET (1) as a function of a control signal (12) with an actuating value of the at least one actuating variable (U1, U2, R1, R2), which is changed compared to the reference actuating value of the actuating variable (U1, U2, R1, R2) according to the change (ΔU1, ΔU2, ΔR1, ΔR2) ascertained by the evaluation unit (7).

9. The actuating arrangement (3) as claimed in claim 8, wherein the control unit (5) has a controllable switching-on voltage source (13) for generating a variable switching-on actuating voltage (U1) for switching on the MOSFET (1).

10. The actuating arrangement (3) as claimed in claim 8 or 9, wherein the control unit (5) has a controllable switching-off voltage source (15) for generating a variable switching-off actuating voltage (U2) for switching off the MOSFET (1).

11. The actuating arrangement (3) as claimed in one of claims 8 to 10, wherein the control unit (5) has a controllable switching-on resistance unit (R1) for generating a variable switching-on gate resistance (R1) for switching on the MOSFET (1).

12. The actuating arrangement (3) as claimed in one of claims 8 to 11, wherein the control unit (5) has a controllable switching-off resistance unit (R2) for generating a variable switching-off gate resistance (R2) for switching off the MOSFET (1).

13. The actuating arrangement (3) as claimed in one of claims 8 to 12, with a measurement apparatus (9) for capturing actual values of at least one operating characteristic variable (U, T), the influence of which on the switching behavior of the MOSFET (1) is taken into consideration in the characteristic block.

14. The actuating arrangement (3) as claimed in claim 13, wherein the measurement apparatus (9) is embodied to capture actual values of an operating voltage (U) and/or an operating temperature (T) of the MOSFET (1).

15. A current converter (30), in particular traction current converter, with at least one MOSFET (1) and an actuating arrangement (3), embodied as claimed in one of claims 8 to 14, for actuating the MOSFET (1).
